(19) United States
(12) Patent Application Publication
(10) Pub. No.: US 2012/0216854 A1
(43) Pub. Date: Aug. 30, 2012

(54) Surface-Passivated Regenerative Photovoltaic and Hybrid Regenerative Photovoltaic/Photosynthetic Electrochemical Cell

(76) Inventors: Christopher E.D. Chidsey, San Francisco, CA (US); Paul C. McIntyre, Sunnyvale, CA (US)

(21) Appl. No.: 13/406,319

(22) Filed: Feb. 27, 2012

Related U.S. Application Data
(60) Provisional application No. 61/464,014, filed on Feb. 25, 2011.

(51) Int. Cl. H01L 31/042

(52) U.S. Cl. 136/248; 136/252; 136/246

(57) ABSTRACT

A photoelectrochemical regenerative photovoltaic cell is provided that includes an electrode structure having a semiconductor photoelectrode layer, and a pinhole-free metal oxide layer disposed on the semiconductor photoelectrode layer forming the electrode structure, where the pinhole-free metal oxide layer is less than 10 nm in thickness, where the thickness of the pinhole-free metal oxide layer protects the semiconductor photoelectrode layer from i) oxidation, ii) dissolution, or i) and ii) when in contact with an electrolyte solution, where the pinhole-free metal oxide layer has a band gap that is transparent to solar radiation and provides band offsets that permit facile electron or hole transport between the electrolyte solution and the semiconducting photoelectrode.

### CROSS-REFERENCE TO RELATED APPLICATIONS

This application claims priority from U.S. Provisional Patent Application 61/464,014 filed Feb. 25, 2011, which is incorporated herein by reference. U.S. Provisional Patent Application 61/464014 filed Feb. 25, 2011 is related to application Ser. No. 12/753,234, filed on Apr. 2, 2010 and hereby incorporated by reference in its entirety. application Ser. No. 12/753,234 claims the benefit of provisional application 61/166,701, filed on Apr. 3, 2009, and hereby incorporated by reference in its entirety.

### FIELD OF THE INVENTION

The current invention relates to photoelectrochemical regenerative photovoltaic cells. More particularly, the invention relates to an electrode structure for photoelectrochemical regenerative photovoltaic cells.

### BACKGROUND OF THE INVENTION

Photoelectrochemical cells can function as regenerative photovoltaic cells, in which reduction/oxidation (redox) reactions at the cathode/anode surfaces transfer charge across an electrolyte interposed between the electrode surfaces with no overall change in the chemical state of species in solution. At least one of these two electrodes is a light-absorbing semiconductor. The process of electron-hole pair generation in the semiconductor produces a photovoltage that can be used to do work when the cell is attached to an external electrical load. Photoelectrochemical cells can also function as photosynthetic cells, in which reduction/oxidation (redox) reactions at the cathode/anode surfaces transfer charge across an electrolyte interposed between the electrode surfaces with a net conversion of one or more species in solution into a new chemical form. An example of such a cell is a photoelectrochemical cell for solar hydrogen generation by oxidation of water molecules at the anode surface and reduction of the resulting protons at the cathode surface. The redox reactions induce oxidation and/or dissolution at the surface of the semiconductors, causing degradation or failure of the device.

What is needed is a structure for electrodes used in photoelectrochemical regenerative photovoltaic cells that protects semiconductors from oxidation and/or dissolution either in entirely photovoltaic operation or during operation of a photoelectrochemical cell that can be switched between switched photovoltaic and photosynthetic modes (a hybrid photovoltaic/photosynthetic cell).

### SUMMARY OF THE INVENTION

To address the needs in the art, a photoelectrochemical regenerative photovoltaic cell is provided that includes an electrode structure having a semiconductor photoelectrode layer, and a pinhole-free metal oxide layer disposed on the semiconductor photoelectrode layer forming the electrode structure, where the pinhole-free metal oxide layer is less than 10 nm in thickness, where the thickness of the pinhole-free metal oxide layer protects the semiconductor photoelectrode layer from i) oxidation, ii) dissolution, or i) and ii) when in contact with an electrolyte solution, where the pinhole-free metal oxide layer has a band gap that is substantially transparent to solar, where the band gap gives sufficiently small energy barriers to allow facile conduction of electronic carriers from the semiconductor photoelectrode to species to be reduced or oxidized in the electrolyte solution, and a counter electrode to the photoelectrode.

According to one aspect of the invention, the pinhole-free metal oxide layer includes a redox catalyst that operates on water molecules or ions dissolved in the electrolyte solution.

In another aspect of the invention, the photoelectrode can be either an anode or a cathode in a photoelectrochemical regenerative photovoltaic cell.

In a further aspect of the invention, the pinhole-free metal oxide layer includes an atomic layer deposited pinhole-free metal oxide layer or a chemical vapor deposited pinhole-free metal oxide layer, where the depositions of this layer are controlled by the kinetics of a surface reaction of a deposition precursor.

According to one embodiment of the invention, the photoelectrochemical regenerative photovoltaic cell further includes a reflective metal substrate, where the reflective metal substrate is disposed on a bottom side of the cell where it could serve as one electrical contact to the cell and a transparent conducting layer on the top-side of the cell as the other electrical contact. The semiconducting layer or layers, the pinhole-free oxide layer or layers and the electrolyte are disposed between the top contact and the substrate such that light enters through the top contact but is reflected back into the semiconductor by the metal substrate.

In another aspect of the current embodiment, the transparent layer includes a conductive oxide, a porous top electrode or a grid top electrode.

In one aspect of the current embodiment the photoelectrochemical regenerative photovoltaic cell further includes an external circuit connected to the metal electrode and the semiconductor photoelectrode layer, where the operation of the photoelectrochemical cell can be switched between operation as a photosynthesis fuel storage device and a photovoltaic device by changing the external circuit and the composition of the electrolyte. Here, the stored fuel includes stored chemical bonds of H₂ and O₂.

According to another embodiment, the photoelectrochemical regenerative photovoltaic cell further includes a second the semiconductor photoelectrode layer of a second electrode structure, where the pinhole-free metal oxide layer of the first electrode structure and the pinhole-free metal oxide layer of the second electrode structure interface the electrolyte solution, where ions in the electrolyte solution cycle between the first electrode structure and the second electrode structure while undergoing oxidation and reduction, a porous or grid transparent conducting oxide layer that provides external electrical contact to the photoelectrochemical regenerative photovoltaic cell, and a transparent layer disposed to encapsulate the porous or grid transparent conducting oxide layer and the second semiconductor photoelectrode layer, where the first semiconductor photoelectrode layer of the first electrode structure includes a bandgap that is larger than a band gap of the second semiconductor photoelectrode layer of the second electrode structure. In this embodiment, incident radiation is absorbed selectively by the two photoelectrodes, so that incident light first passes through the higher band gap photoelectrode and then passes through the lower band gap photoelectrode.

In one aspect of the current embodiment, the first semiconductor photoelectrode layer includes material such as crystalline Ge and crystalline Si, crystalline GaAs, InP, amorphous Si, copper zinc tin sulphide (CZTS), copper indium gallium selenide (CIGS), or CdSe.

In another aspect of the current embodiment, the second semiconductor photoelectrode layer includes material such as crystalline GaAs, InP, amorphous Si, copper zinc tin sulphide (CZTS), copper indium gallium selenide (CIGS), CdSe, GaP, and ZnO.

In yet another aspect of the current embodiment, the transparent layer comprises a conductive oxide, a porous top electrode or a grid top electrode.

In another aspect of the current embodiment, the two semiconducting photoelectrode layers (with different band gaps), each coated with a pinhole-free metal oxide layer, are separated by a polymer electrolyte or conductive polymer though which redox species move between the two photoelectrode.

Another embodiment of the invention includes positioning the two semiconducting photoelectrode layers (with different band gaps), each coated with a pinhole-free metal oxide layer, in a back-to-back arrangement in a photoelectrochemical cell. In this embodiment, incident radiation is absorbed selectively by the two photoelectrodes, so that incident light first passes through the higher band gap photoelectrode and then passes through the lower band gap photoelectrode.

In another embodiment of the invention, two semiconducting photoelectrodes each coated with a pinhole-free metal oxide layer would be positioned side-by-side in a photoelectrochemical cell, so that each is exposed to the full spectrum of incident radiation.

According to one aspect of the invention, the electrolyte solution includes an ion having a redox energy level in the range of the bandgap energy of the semiconducting photoelectrode layer.

In another aspect of the invention, an optically transparent thin charge-accumulation layer, such as an inert metal layer, between the metal oxide and the electrolyte provides for establishment of an electrochemical double layer of charge and an electrostatic potential offset that allows operation with an ion in the electrolyte having its redox energy level outside the bandgap energy of the semiconductiong photoelectrode layer.

### BRIEF DESCRIPTION OF THE DRAWINGS

FIG. 1 shows a schematic drawing of a regenerative photovoltaic cell with a surface-protected semiconducting photoanode and a metal cathode, according to one embodiment of the invention.

FIG. 2 shows a schematic drawing of surface protected semiconductors for both the anode and cathode to increase the photovoltage available to the device, according to one embodiment of the invention.

FIG. 3 shows a schematic drawing of surface protected semiconductors for both the anode and cathode with the electrodes shorted for energy storage, according to one embodiment of the invention.

FIG. 4 shows a graph of current-voltage data obtained from a regenerative photovoltaic cell using a nanocomposite surface protected anode, according to one embodiment of the invention.

### DETAILED DESCRIPTION

According to one embodiment, the invention includes a semiconductor structure that enables the operation a photoelectrochemical cell for both highly efficient photovoltaic energy conversion and photosynthetic energy storage (e.g. water splitting). Possible embodiments of the invention include a potentially inexpensive multijunction photovoltaic cell. Ultimate applications could include utility-scale solar energy production with local energy storage capability.

One embodiment of the current invention includes an electrode structure for use in photoelectrochemical regenerative photovoltaic cells. The electrode structure incorporates an ultra-thin and pinhole-free metal oxide layer that protects semiconductors from oxidation and/or dissolution. The deposition of such layers can be achieved by atomic layer deposition or another form of chemical vapor deposition in which the deposition process is controlled by the kinetics of a surface reaction of the precursor. The protection layer in this approach is sufficiently thin (e.g. <10 nm) and has an appropriate (sufficiently large, e.g. >2.5 eV) band gap so as to be largely transparent to solar radiation. It is also sufficiently thin (e.g. <10 nm) and has appropriate (sufficiently small e.g. <2 eV) band offsets to electron and hole transport to present a low electrical resistance for current transport between the electrolyte and semiconducting electrodes. This layer may itself be an effective catalyst for redox processes involving water molecules or ions dissolved in solution, or it may be combined in a, still very thin, composite stack with layers of such catalysts. A regenerative photovoltaic cell including this protective surface layer exhibits low overpotentials for the desired redox reactions and it will efficiently absorb solar radiation, resulting in a high photovoltaic efficiency. It will also exhibit long lifetimes in service without oxidation and/or corrosion of the semiconductor electrode(s) in the cell. This surface protection of photoelectrodes can be employed in either a photovoltaic (PV) cell or in a hybrid PV/photosynthetic cell.

A key aspect of this invention is that the surface protection layer can be sufficiently effective in preventing oxidation and/or dissolution of the semiconductor that it is possible for the cell to be used both for photovoltaic (PV) energy conversion and for photosynthesis (PS) of fuel to store incident solar radiation in the form of chemical bonds (e.g. as H₂ and O₂). By shorting the cathode and anode through an external circuit and exchanging the electrolyte the photoelectrochemical cell operation can be switched from regenerative PV to PS, a potentially valuable feature for storage of solar electricity. Depending on the bandgap of the semiconducting photoelectrode, an externally-applied bias may or may not be required to supplement the photovoltage of the semiconductor and achieve the potential needed for fuel synthesis.

A further embodiment of this invention would use surface protected semiconductors for both the anode and cathode, thus increasing the photovoltage available to the device. Such a surface protected semiconductor photoelectrochemical cell is an example of a multijunction solar cell that simplifies the state-of-the-art solid-state (monolithic) multijunction cells. The “top” semiconductor layer in the structure has a bandgap larger than that of the counter photoelectrode (the “bottom” semiconductor layer). It selectively absorbs shorter-wavelength solar photons and transmits longer-wavelength photons to underlying layer, where they are absorbed. The thicknesses of these two semiconductors are disposed to achieve matching of their respective photocurrents. Here, the additional semiconductor layers, also separated from their neighbors by an aqueous electrolyte, can be added to the structure in a stacked fashion to provide even higher photovoltaic efficiency. For two junction devices some exemplary semiconducting material combinations for these two layers include GaAs and Ge, or amorphous Si and crystalline Si, respectively.

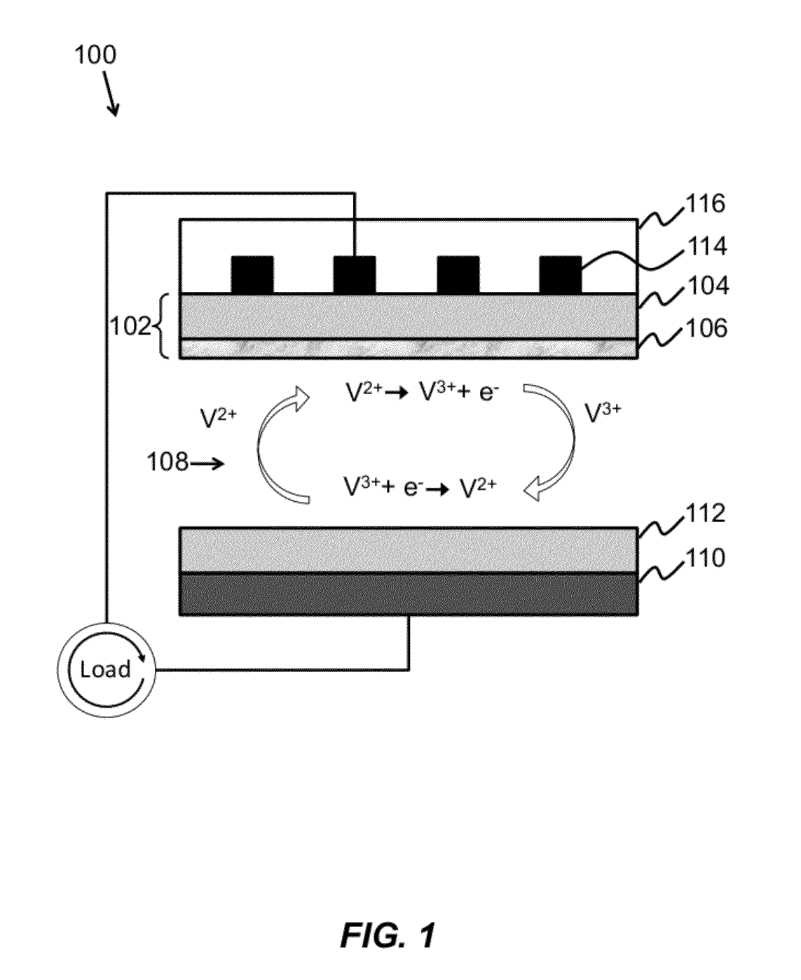

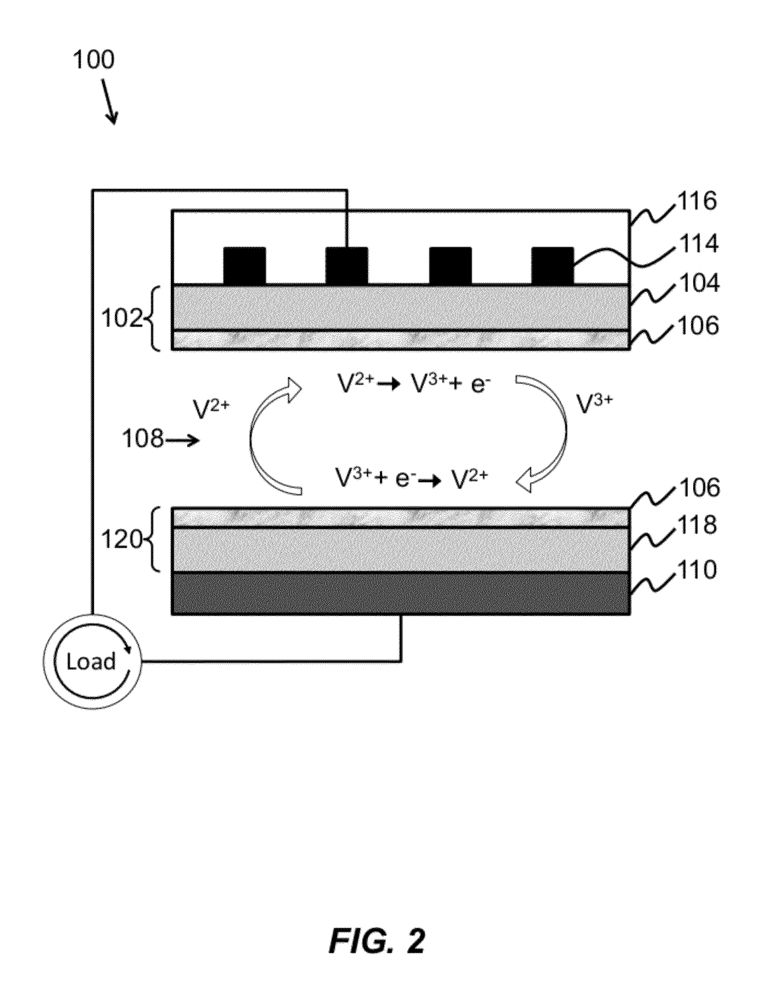

Important features of the cell embodiment enabled by the invention include use of an interposed aqueous electrolyte that can function as coolant for the device. This is important in concentrated solar applications, in which such multijunction hybrid PV/PS cells are likely to be used. Moreover, the flow of the electrolyte could also be used to easily remove dissolved oxygen and hydrogen prior to nucleation of O₂ and H₂ gas bubbles, which could thus be performed in cell exit ports remote from the regions shown in FIG. 1 and FIG. 2.

Some advantages of the invention include the combination of both highly efficient photovoltaic energy conversion (potentially using an inexpensive multijunction architecture) with the capability of switching the device to a photosynthetic mode of operation in which splitting water to generate hydrogen and oxygen can be used to store energy.

The hydrogen and oxygen could then be reacted in a fuel cell, for example, to recover the stored energy when the sun is not shining Therefore, electricity generation and storage can be combined at the same physical site.

The key feature of some embodiments of the invention include the innovative photoelectrochemical cell structure described herein has the ability to protect the surface different semiconductor anodes and cathodes using an ultra-thin nanocomposite surface layer. This nanocomposite, which is grown by atomic layer deposition or a similar method for pin-hole free deposition of ultra-thin films, simultaneous protects semiconductor surfaces from oxidation/dissolution, catalyzes redox surface reactions, and permits both photon and electron transport across the electolyte/electrode interface.

A photoelectrochemical regenerative photovoltaic cell 100 with a surface-protected semiconducting photoanode and a metal cathode is provided in FIG. 1 that includes an electrode structure 102 having a semiconductor photoelectrode layer 104, and a pinhole-free metal oxide layer 106 disposed on the semiconductor photoelectrode layer forming the electrode structure 102, where the pinhole-free metal oxide layer 106 is less than 10 nm in thickness, where the thickness of the pinhole-free metal oxide layer 106 protects the semiconductor photoelectrode layer 104 from i) oxidation, ii) dissolution, or i) and ii) when in contact with an electrolyte solution 108, where the pinhole-free metal oxide layer 106 has a band gap that is transparent to solar radiation and offsets electron and hole transport where current transport occurs between the electrolyte solution 108 and the semiconducting photoelectrode layer 104. FIG. 1 further shows the photoelectrochemical regenerative photovoltaic cell 100 having a reflective metal substrate 110, a metal electrode 112, where the reflective metal substrate 110, which provides external electrical contact to the cell 100, is disposed on a bottom side of the metal electrode 112, and a transparent conducting oxide 114 (porous or grid top electrode) disposed on the semiconducting photoelectrode layer 104, which provides external electrical contact to the cell 100, and an encapsulating polymer or glass layer (transparent layer) 116 disposed to encapsulate the semiconductor photoelectrode layer 104 (photoanode is shown in this example), where the transparent conducting oxide 114 provides external electrical contact to the photoelectrochemical regenerative photovoltaic cell 100, where the pinhole-free metal oxide layer 106 and a top side of the metal electrode 112 (metal cathode is shown in this example) interface the electrolyte solution 108, where the electrolyte solution 108 is disposed between the metal electrode 112 and the pinhole-free metal oxide layer 106, and where ions in the electrolyte solution 108 cycle between the metal electrode 112 and the electrode structure 102 while undergoing oxidation and reduction. The electrolyte solution 108 is an aqueous electrolyte solution containing an ion with redox energy level in the bandgap energy range of the semiconducting electrode [vanadium II/vanadium III is shown in this example].

A further embodiment of this invention uses the electrode structure 102 (surface protected semiconductors) for both the anode and cathode, thus increasing the photovoltage available to the photoelectrochemical regenerative photovoltaic cell 100, as shown in the example structure of FIG. 2. Here, the photoelectrochemical regenerative photovoltaic cell 100 includes a reflective metal contact substrate 110, which provides external electrical contact to the cell 100, disposed on a bottom side of a first semiconductor photoelectrode layer (semiconducting photocathode is shown in this example) 118 of a first electrode structure 120, pinhole-free metal oxide layer 106 disposed on a second semiconductor photoelectrode layer (photoanode is shown in this example) 104 of a second electrode structure 102, where the pinhole-free metal oxide layer 106 (which may contain catalyst) of the first electrode structure 120 and the pinhole-free metal oxide layer (which may contain catalyst) 106 of the second electrode structure 102 interface the electrolyte solution 108, where ions in the electrolyte solution 108 such as an aqueous electrolyte solution containing an ion with redox energy level in the bandgap energy range of the semiconducting electrode (vanadium II/vanadium III in aqueous solution is shown in this example), cycle between the first electrode structure 120 and the second electrode structure 102 while undergoing oxidation and reduction, porous or grid transparent conducting oxide layer 114, and a transparent layer (polymer or glass layer) 116 disposed to encapsulate the porous or grid transparent conducting oxide layer 114 and the second semiconductor photoelectrode layer 104, where the porous or grid transparent conducting oxide layer 114 provides external electrical contact to the photoelectrochemical regenerative photovoltaic cell 100, where the first semiconductor photoelectrode layer 118 of the first electrode structure 120 includes a bandgap that is larger than a band gap of the second semiconductor photoelectrode layer 104 of the second electrode structure 102.

The surface-protected semiconductor photoelectrochemical cell shown in FIG. 2 is an example of a much more practical-to-fabricate multijunction solar cell than the state-of-the-art solid state (monolithic) multijunction cells. Semiconductor photoelectrode layer 104 in the structure is a semiconductor with a bandgap larger than that of the counter semiconductor photoelectrode layer 118. It (104) selectively absorbs shorter-wavelength solar photons and transmits longer-wavelength photons to the counter semiconductor photoelectrode layer 118, where they will be absorbed. The thicknesses of these two semiconductors (104/118) is engineered to achieve matching of their respective photocurrents.

The pinhole-free metal oxide layer 106 may itself be an effective catalyst for redox processes involving water molecules or ions dissolved in solution, or it may be combined in a, still very thin, composite stack with layers of such catalysts.

In one aspect of the current embodiment, the first semiconductor photoelectrode layer includes material such as crystalline Ge and crystalline Si, crystalline GaAs, InP, amorphous Si, copper zinc tin sulphide (CZTS), copper indium gallium selenide (CIGS), or CdSe.

In another aspect of the current embodiment, the second semiconductor photoelectrode layer includes material such as crystalline GaAs, InP, amorphous Si, copper zinc tin sulphide (CZTS), copper indium gallium selenide (CIGS), CdSe, GaP, and ZnO.

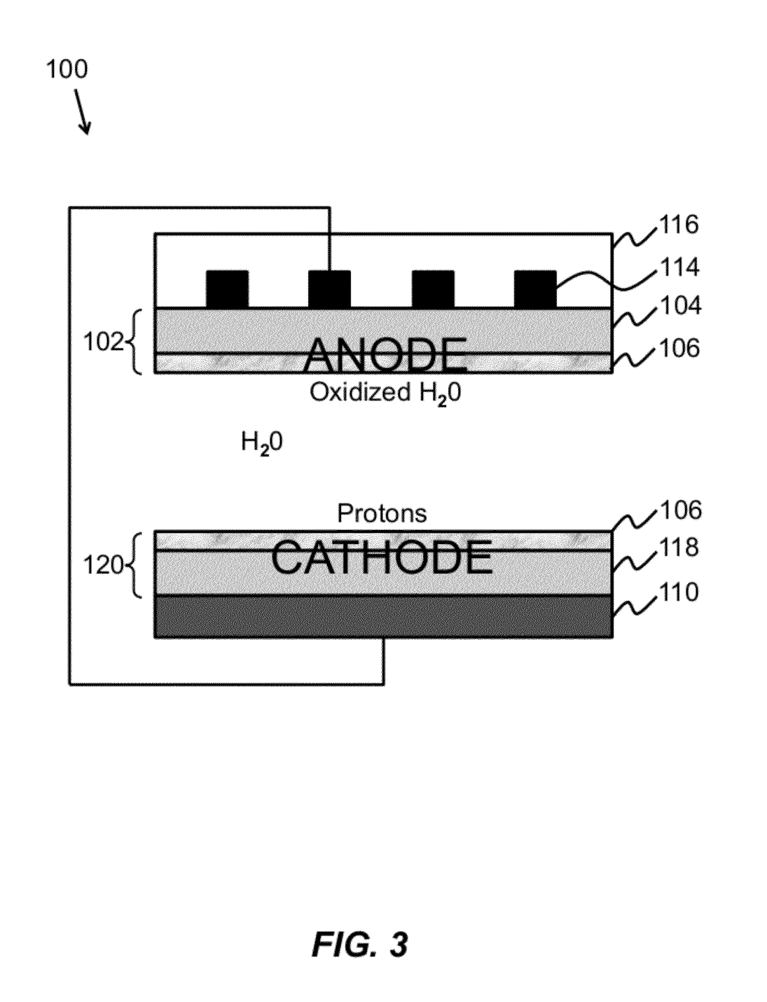

FIG. 3 shows the photoelectrochemical cell 100 disposed for solar hydrogen generation by oxidation of water molecules at the anode surface and reduction of the resulting protons at the cathode surface. Here, the photoelectrochemical cell 100 is shorted and the photovoltage provided by light absorption by one or both of the electrodes (114,110) provides the driving force for fuel synthesis reaction. This hybrid PV/PS embodiment provides significant advantages. It combines both highly efficient photovoltaic energy conversion (potentially using an inexpensive multijunction architecture) with the capability of switching the device to a photosynthetic mode of operation in which splitting water to generate hydrogen and oxygen is used to store energy. The hydrogen and oxygen is then reacted in a fuel cell, for example, to recover the stored energy when the sun is not shining Therefore, electricity generation and storage are combined at the same physical site.

Applications include large-scale, efficient solar energy conversion with local energy storage capability, to compensate for the intermittency of incident solar radiation.

Several embodiments are possible, for example the working electrodes in the cell could be either 1) a semiconductor (absorber) and a metal or 2) two or more semiconductors, possibly with different bandgaps. The latter structure constitutes a multijunction PV cell, which can achieve very high solar energy conversion efficiencies. However, unlike a conventional multijunction cell, charge transport between the different light absorbing layers is mediated by ion transport through an interposed electrolyte. This eliminates the need for coherent epitaxy between the layers used in a state-of-the-art monolithic multijunction PV cell, and should result in much lower cost both per unit area and per Watt.

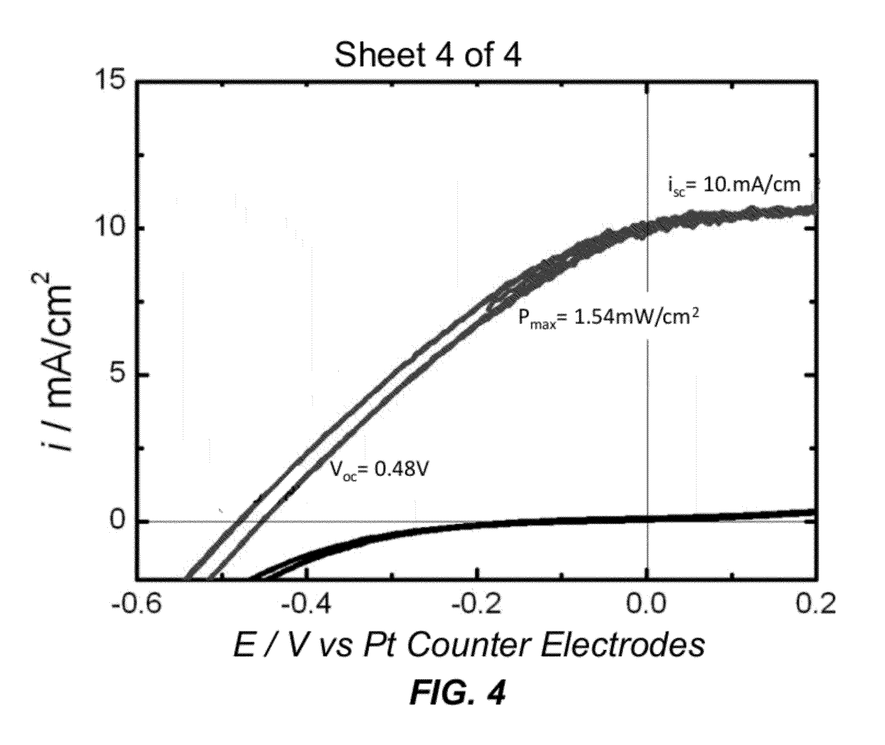

FIG. 4 shows current-voltage data obtained from a regenerative photovoltaic cell using a nanocomposite, surface protected anode having a 3 nm Ir/24 cycles of ALD-TiO₂/n-Si structure. The electrolyte was 0.1 M of ferricyanide/ferrocyanide solution with 0.1 M NaOH. This exemplary device has an efficiency of ˜1.6%, but the layer thicknesses were not optimized to increase the short circuit current and a very small Pt cathode wire was used (rather than a Pt mesh cathode) which may limit the effective rate of the reduction reaction in the cell. These initial data show a single-junction, surface-protected PV cell is reduced to practice.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art.

For example, instead of a liquid electrolyte, a polymer electrolyte or conductive polymer could be interposed between two photoelectrodes which have surfaces protected by the pinhole-free metal oxide coating of <10 nm thickness of this invention. A polymer electrolyte would allow regenerative photovoltaic operation of a two junction device by redox reactions at the electrode surfaces involving species dissolved in the polymer electrolyte. However, the resulting two junction regenerative device would be suitable for fabrication by additive layering methods typical of solid-state photovoltaic devices. This would avoid, for example, the need to fabricate gap structures that would later be filled with a liquid electrolyte, if a liquid electrolyte were used to dissolve the redox species.

Alternatively, a two junction device which absorbs the energy of incident radiation selectively can also be fabricated in a back-to-back arrangement, in which a transparent and electronically conductive medium (e.g. a glass substrate coated with a thin transparent conductor on both sides) connects the back side of one photoelectrode to that of the other. A pinhole-free metal oxide coating protects the surface of each photoelectrode that is exposed to the electrolyte solution while allowing facile electronic carrier transport between the electrode and the electrolyte to sustain electrochemical reactions on the respective photoelectrode surfaces.

Furthermore, a two junction device can be made by positioning two photoelectrodes, each coated with a pinhole-free metal oxide layer, side-by-side in a photoelectrochemical cell, so that each is exposed to the full spectrum of incident radiation.

All such variations are considered to be within the scope and spirit of the present invention as defined by the following claims and their legal equivalents.

What is claimed:

1. A photoelectrochemical regenerative photovoltaic cell, comprising:
a. an electrode structure, wherein said electrode structure comprises:
i. a semiconductor photoelectrode layer;
ii. a pinhole-free metal oxide layer disposed on said semiconductor photoelectrode layer forming an electrode structure, wherein said pinhole-free metal oxide layer is less than 10 nm in thickness, wherein said thickness of said pinhole-free metal oxide layer protects said semiconductor photoelectrode layer from i) oxidation, ii) dissolution, or i) and ii) when in contact with an electrolyte solution, wherein said pinhole-free metal oxide layer comprises a band gap that is substantially transparent to solar radiation, wherein said band gap gives sufficiently small energy barriers to allow facile conduction of electronic carriers from said semiconductor photoelectrode to species to be reduced or oxidized in said electrolyte solution; and
b. a counter electrode to said photoelectrode.

2. The photoelectrochemical regenerative photovoltaic cell of claim 1, wherein said pinhole-free metal oxide layer comprises a redox catalyst, wherein said redox catalyst operates on water molecules or ions dissolved in said electrolyte solution.

3. The photoelectrochemical regenerative photovoltaic cell of claim 1, wherein said photoelectrode comprises an anode or a cathode in a photoelectrochemical regenerative photovoltaic cell.

4. The photoelectrochemical regenerative photovoltaic cell of claim 1, wherein said pinhole-free metal oxide layer comprises an atomic layer deposited pinhole-free metal oxide layer or a chemical vapor deposited pinhole-free metal oxide layer, wherein said depositions are controlled by the kinetics of a surface reaction of a deposition precursor.

5. The photoelectrochemical regenerative photovoltaic cell of claim 1 further comprises:
a. a reflective metal substrate;
b. a metal counter electrode, wherein said reflective metal substrate is disposed on a bottom side of said metal counter electrode, wherein transmitted sunlight is reflected into an active semiconductor junction of said photoelectrode layer; and
c. a transparent layer disposed to encapsulate said semiconductor photoelectrode layer, wherein said transparent layer provides external electrical contact to said photoelectrochemical regenerative photovoltaic cell, wherein said pinhole-free metal oxide layer and a top side of said metal counter electrode both interface said electrolyte solution, wherein said electrolyte solution is disposed between said metal electrode and said pinhole-free metal oxide layer, wherein ions in said electrolyte solution cycle between said metal electrode and said electrode structure while undergoing oxidation and reduction.

6. The photoelectrochemical regenerative photovoltaic cell of claim 5 further comprises an external circuit connected to said metal counter electrode and said semiconductor photoelectrode layer, wherein said photoelectrochemical cell comprises a photosynthesis fuel storage device, a regenerative photovoltaic device, or a hybrid photovoltaic/photosynthetic device.

7. The photoelectrochemical regenerative photovoltaic cell of claim 6, wherein said stored fuel comprises H₂ and O₂.

8. The photoelectrochemical cell of claim 5, wherein said transparent layer comprises a conductive oxide, a porous top electrode or a grid top electrode, wherein said porous top electrode comprises a substantially light-transmitting random network of conductive elements.

9. The photoelectrochemical regenerative photovoltaic cell of claim 1 further comprises:
a. a first said semiconductor photoelectrode layer of a first said electrode structure;
b. a second said semiconductor photoelectrode layer of a second said electrode structure, wherein said second semiconductor photoelectrode layer comprises said counter electrode in said photoelectrochemical cell, wherein said pinhole-free metal oxide layer of said first electrode structure and said pinhole-free metal oxide layer of said second electrode structure interface said electrolyte solution, wherein ions in said electrolyte solution cycle between said first electrode structure and said second electrode structure while undergoing oxidation and reduction on each respective metal oxide layer-coated photoelectrodes and wherein said first semiconductor photoelectrode layer of said first electrode structure comprises a bandgap that is larger than a band gap of said second semiconductor photoelectrode layer of said second electrode structure; and
c. at least one transparent conductor layer on at least one of said photoelectrode layers, wherein said transparent conductor layer is an external electrical contact to said photoelectrochemical regenerative photovoltaic cell.

10. The photoelectrochemical regenerative photovoltaic cell of claim 9, wherein said first semiconductor photoelectrode layer comprises material selected from the group consisting of crystalline Ge, crystalline Si, crystalline GaAs, InP, amorphous Si, copper zinc tin sulphide (CZTS), copper indium gallium selenide (CIGS), and CdSe.

11. The photoelectrochemical regenerative photovoltaic cell of claim 9, wherein said second semiconductor photoelectrode layer comprises material selected from the group consisting of crystalline GaAs, InP, amorphous Si, copper zinc tin sulphide (CZTS), copper indium gallium selenide (CIGS), CdSe, GaP and ZnO.

12. The photoelectrochemical regenerative photovoltaic cell of claim 9, wherein two said semiconductor photoelectrode layers are separated by a polymer electrolyte, wherein redox species move between the two photoelectrode layers through said polymer electrlolyte.

13. The photoelectrochemical cell of claim 9, wherein said transparent layer comprises a conductive oxide, a porous top electrode or a grid top electrode.

14. The photoelectrochemical regenerative photovoltaic cell of claim 9 further comprises an external circuit connected to said metal counter electrode and said semiconductor photoelectrode layer, wherein said photoelectrochemical cell comprises a photosynthesis fuel storage device, a regenerative photovoltaic device, or a hybrid photovoltaic/photosynthetic device.

15. The photoelectrochemical regenerative photovoltaic cell of claim 1, wherein said electrolyte solution comprises an ion having a redox energy level, wherein said redox energy level is within the range of the bandgap energy of said semiconducting photoelectrode layer.
